(19) United States
(12) Patent Application Publication
(10) Pub. No.: US 2014/0266488 A1
(43) Pub. Date: Sep. 18, 2014

(54) Pulse Width Modulation (PWM) Utilizing Stored Signals Having Stochastic Characteristics

(71) Applicant: Douglas Arthur Bors, Bellevue, WA (US)

(72) Inventor: Douglas Arthur Bors, Bellevue, WA (US)

(21) Appl. No.: 13/838,879

(22) Filed: Mar. 15, 2013

(51) Int. Cl. H03K 7/08

(52) U.S. Cl. CPC H03K 7/08
USPC 332/109

(57) ABSTRACT

A system and method for generating a digital pulse width modulation (PWM) control signal for a power transfer device that includes providing a digital PWM signal having a stochastic characteristic and control information, storing one or more of the digital PWM signals and retrieving the signal from the storage device to determine the output of a power transfer device. The stored digital PWM signals exhibit selected frequency domain characteristics after being configured and preselected to minimize undesirable characteristics such as harmonic signatures, audible noise, component vibration, and frequency-domain energy peaks.

### TECHNICAL FIELD

The present invention relates, in general, to power transfer devices and, more particularly, to electrical power transfer devices wherein pulse width modulation is used as a control method.

### BACKGROUND ART

In applicant's prior invention, as described in U.S. Pat. No. 6,510,068, the practice in the related technical field was extended from one that utilizes deterministic waveforms to one where practitioners could utilize random waveforms or utilize deterministic signals where elements of those signals had been randomized (shifted) so that specific time domain signatures could be eliminated (or reduced) in resulting PWM control schemes. This holds promise for increased efficiencies in many classes of devices and to increased reliability in these same devices.

Control schemes that involve shifting the timing of control signals generally introduce an increased delay in the time between a change in feedback and a change in the output of the controller. Promise for increased efficiencies in many devices depends on a relative reduction in switching events internal to a controller and this implies more time between switching events and, in cases where stochastic characteristics are introduced by varying the delay of individual PWM pulse edges, further implies increased delay. This relationship is identified in related art.

U.S. Pat. No. 6,927,534—explores a method to compensate for delay in a PWM control circuit.

U.S. Pat. No. 7,421,824—establishes a method to limit the delay in a PWM control circuit, specifically to avoid instability in the controlled device.

The approaches offered in U.S. Pat. Nos. 6,927,534 and 7,421,824 both relate to mitigating the impact of delay between a feedback signal and the PWM control signal operation.

In general, PWM control schemes are used for many types of power transfer devices and these devices must accommodate many circumstances, including circumstances arising from multi-channel power flow.

U.S. Pat. No. 8,344,699—explores individual phase control in a multi-phase power transfer device.

U.S. Pat. No. 8,344,712—explores phase balancing in a multi-phase power transfer device.

The approaches offered in U.S. Pat. Nos. 8,344,699 and 8,344,712 exemplify the complexity of control required for many PDF control schemes and further suggest the need for rapid and predictable response to changing circumstances at power transfer devices.

The following references may be reviewed with respect to the disadvantages stemming from PWM signals having a stochastic characteristic:
Kirlin et al, IEEE, June 1995
Stankovic et al, IEEE (Control Systems Technology) Vol. 5, No. 1, January 1997
Jocobina et al, IEEE (Industrial Electronics) Vol. 45, No. 5, October 1998
Kirlin et al, IEEE (Industrial Electronics) Vol. 49, No. 2, April 2002
Ess, U.S. Pat. No. 6,727,765 B1, Filed Jun. 28, 2002
Trzynadlowski et al, IEEE (Power Electronics) Vol. 20, No. 1, January 2005

In every case, authors are attempting to identify means and methods for formulating and measuring aspects of PWM signals with stochastic behavior as opposed to deterministic PWM control schemes. In several cases authors have identified a delay associated with control pathways where stochastic behavior is introduced. In no case above has an author suggested storing a control pattern including stochastic characteristics as a means for reducing that delay.

Further, related art has clearly identified the use of storage of PWM control patterns in many applications, but related art does not connect the storage to advantages further related to PWM signals having stochastic characteristics. Reference to the following eight patents exemplifies this statement.

Control patterns stored in memory is a useful approach, for various reasons, for improving PWM control schemes and circuits, but in each reference cited below, the advantage related to storing a PWM control pattern encoded to maintain stochastic characteristics is not demonstrated. Instead, the references help to support the assertion that storing the collection of PWM signals with stochastic characteristics in memory results in an unanticipated or unexpected advantage that is specific to that type of control signal. Specifically, the time delay required to establish a stochastic result without increasing PWM switching rates is avoided with the storage and retrieval scheme, wherein retrieval is accomplished as a control step.

Ono, U.S. Pat. No. 4,356,544, Filed May 29, 1981

The referenced patent utilizes a circuit with digital memory arranged to store an image of a PWM waveform, encoded as a collection of n slices (i.e., n parts) of 180 degrees of a sinusoidal waveform. The storage scheme described allows the circuit to vary the fundamental frequency of the output voltage waveform by changing the timing applied to each slice of the waveform. The description suggests that the resulting circuit provides better digital pattern replication, better three phase synchronization, better switching stability, and better accuracy related to the output waveform fundamental frequency, as compared to prior art.

The circuit described and shown in diagrams does not include a voltage feedback pathway; instead it is focused on speed control.

The description identifies that one of the advantages relates to moving away from analog circuits in order to be able to place the entire logical portion of the control circuit in a large scale integration (LSI) chip, rather than requiring one analog chip and one digital chip to implement the motor controller logic.

The time required to operate the prior art (analog circuit) and the time to look-up stored information and then to form the output waveform is similar. In fact, the digital circuit may be slower. However, the difference in timing between the two circuits is not important with respect to the operation of speed control of motors. The advantages of Ono relate to issues other than timing relative to a stored control pattern.

The memory system described in Ono stores one pattern. The system uses this one pattern to subsequently calculate transitions necessary to create speed control. The description of Ono does not include selection from among a collection of patterns.

Deguchi, U.S. Pat. No. 4,636,928, Filed Sep. 27, 1984

The referenced patent utilizes a circuit with memory to store multiple control cell information, wherein one control cell describes the characteristics of one pulse further divided into smaller timing units to enable the circuit logic to identify, select, and use the cell information for control of a variable speed motor. The circuit described by Deguchi comprises a compact control signal creation algorithm where selection of cell information is a portion of the algorithm. The circuit must be fast with respect to the counting required to identify the timing mark used to turn off a control data segment. However, the circuit shown does not suggest a feedback loop with respect to speed or voltage output, so there is no stability issue with respect to a feedback loop. Further, the control element selected encodes a deterministic value and no further computational work is required except to map the cell pattern into a stopping time within the PWM pulse.

The advantages of Deguchi relate to issues including the efficiency of calculating timed events relative to a stored control pattern.

The memory system described in Deguchi stores several cell patterns. The system uses one of these patterns to subsequently calculate transitions necessary to create speed control.

The circuit described in Deguchi includes significant calculation (i.e., counting to define transitions) after selecting a cell pattern, and due to its deterministic nature, is not impacted by the delay required for calculating a stochastic transition.

Schauder, U.S. Pat. No. 4,713,745, Filed Jul. 22, 1986

The reference patent uses several memory-based look-up tables. In FIGS. 13A and 13B, these tables are identified in a circuit as PRM1, PRM2, SW1 (data selector), PROMA, PROMB, and PROMC.

PRM1 is a look-up table providing an approximate value for a sin waveform.

PRM2 is a look-up table for a triangle waveform, through a digital to analog converter, to define one of the address bits on PROMA, PROMB, and PROMC.

SW1 (data selector) replaces a logic circuit represented by CTL in FIG. 9.

PROMA, PROMB, and PROMC map switching requirements to switch line signals for the power switching elements CNVA, CNVB, and CNVC. PROMA, PROMB, and PROMC are connected via address lines to two special case address lines, one from the comparator and one from the direction mode control. These two special addressing lines are essentially a direct replacement for a separate logic circuit.

In the case of PRM1, the sin ( ) waveform value is a relatively demanding calculation. Nevertheless, the calculation time is predictable and the use of the sin ( ) look-up table replaces a predictable result with a predictable table function.

In the case of all other look-up tables, the addressing of information is either a replacement for a simple calculation (i.e., a ramp function) or a replacement for a logic circuit.

The essential question here is whether the circuit would be limited with respect to its logical functioning if the look-up tables were not used. Based on the list of look-up functions above, the answer is no. The sin ( ) function could be replaced by an analog sin wave generator and an analog to digital converter. All other tables could be replaced with logic circuits and calculations and operate just as well. Implementing this patent, concerned with vector control of a UFC, is not dependent on the use of look-up tables, nor does the use of look-up tables suggest an unexpected result.

Yokoi, U.S. Pat. No. 4,720,777, Filed Nov. 14, 1986

The reference patent includes one essential look-up table. This table stores information, in a read-only format, related to the cos waveform, that is, a shifted sin waveform.

One teaching of this patent is that the look-up table provides a cost effective, yet accurate means, for presenting the pulse width of a specific pulse in the PWM controller. It does not teach that the look-up table provides an unexpected result regarding its comparison to a waveform-based system that uses a comparator to create individual pulses. Instead, the storage is used to store values that could be calculated, and these numbers are further processed to define when an individual pulse is turned on or off.

Item 16 in FIG. 1 is a ROM memory that stores and provides a digital numeric value representing a value for position on a cos wave. Instead of the stored value saving time after it is retrieved, it requires additional processing, to define a PWM output, plus a timed countdown to define on-off states of a PWN pulse. Since this timed countdown is deterministic, and since speed control is not subject to speed-sensing feedback, this delay is not described as important.

Item 17 in FIG. 1 is a ROM memory that stores and provides a logic pattern to describe the relationship of one portion of a cos waveform to a three-phase switching module.

Implementing this patent, concerned with PWM control of an AC motor, is dependent on the use of look-up tables and on determinant calculations responding to a speed control input voltage, however, the use of look-up tables do not suggest an unexpected result, nor do they avoid a problem presented in the analog mirror of the process.

Kanazawa, U.S. Pat. No. 4,758,938, Filed Feb. 3, 1987

The reference patent stores two distinct PWM patterns and selects between these patterns. The selection between these two patterns represents a pre-defined design point, which is based on frequency. Above a specified frequency, one PWM pattern is selected, below that design point the other PWM pattern is selected. Each PWM pattern is deterministic, and could be calculated. The selection of one pattern vs the other pattern is intended to allow one waveform to apply to starting and low motor-frequency circumstances in hopes of improving overall power efficiency.

In Kanazawa, the advantage of selecting among patterns is to use the best (deterministic) pattern for each running circumstance. It is not required to avoid processing time, but is useful to simplify the control device. The use of look-up tables does not suggest an unexpected result, nor do the look-up tables avoid a problem presented in the analog mirror of the same control process.

Takahashi, U.S. Pat. No. 4,763,060, Filed Oct. 8, 1986

The reference patent stores defined switching patterns for each of three phase components of a switching assembly, plus a zero vector pattern. The system retrieves the stored patterns via a memory address defined by a bidirectional counter, which is connected to a speed control loop.

The selection among switching patterns related to three-phase operation is consistent with a logic circuit defining vector control of a three-phase system. The definition and control of voltage amplitude is informed by a triangular reference waveform and a comparator, not dissimilar to the use of a triangular waveform in an analog PWM circuit.

The selection of a zero vector relates to a condition of speed variance at the motor, specifically motor speed above the desired control speed. As the motor spins faster the PPI control in FIG. 1 modifies a signal to the bidirectional counter and this changes the selection of a vector recovered from memory.

The output of zero vectors could be accomplished via a logic circuit as opposed to the selection of a memory location. The selection of non-zero vectors used to shape the rotary field is pre-calculated and stored in memory, similar to the storage of PWM patterns defined by a triangular waveform and compared to a sin waveform, except that the vectors have been mapped to the rotating voltage path of a rotating motor.

Thus, the use of memory in Takahashi is replacing a calculation method with a predictable time requirement. Its advantage is related to the cost reduction and simplicity of implementation (reference Column 1, line 67 through Column 2, line 2). The use of look-up tables does not suggest an unexpected result, nor do the look-up tables avoid a problem presented in the analog mirror of the same control process.

Takahashi et al, U.S. Pat. No. 4,962,976, Filed Dec. 4, 1989

The reference patent uses memory to store defined switching patterns for each of three phase components of a switching assembly, plus a zero vector pattern, identically to the memory system described in Takahashi, U.S. Pat. No. 4,763,060. The description of the circuit in FIG. 1 includes an identical memory retrieval means, including the addressing bits and address assignments.

The difference between U.S. Pat. Nos. 4,962,976 and 4,763,060 is found in the means for processing the position sensor feedback signal through a delay circuit (a specific integration circuit) to optimize the speed control.

Thus, the use of a look-up table holds the same relationship as described in U.S. Pat. No. 4,763,060 above.

Gritter, U.S. Pat. No. 4,994,950, Filed Jul. 31, 1990

The reference patent uses memory to store patterns required for PWM control for a variable frequency output. The reference patent utilizes look-up tables to map an angular reference to two patterns of sin waveforms. A data selector is used to further map these patterns, stored across a 60-degree segment of the output waveform, onto the full 360-degree output range. A pulse director is used to drive the switches required to control power to the output. The look-up tables and data selector identified above are essentially identical in function to the look-up tables in Schauder, U.S. Pat. No. 4,713,745.

Thus, the use of look-up tables has the same relationship in Gritter as described in U.S. Pat. No. 4,713,745 above.

In each of the eight patents offered as additional reference, furnished to identify the use of look-up tables as described above, the look-up tables offered significant advantages, including lowering the demand on calculation, eliminating the need for mixed analog and digital systems, simplifying implementation by avoiding the use of dedicated logic circuits, and allowing a counter to represent a rotary position in lieu of an analog sin wave. However, in no case did the mapping of information avoid a time delay in the control circuit that was unavoidable in an equivalent analog circuit. Conversely, the analog equivalent of a PWM circuit containing stochastic information requires a time delay that is related to the quality of the stochastic information; the longer the delay in processing, the more impact the stochastic information has with respect to the spread of specific frequency domain energy components.

Thus, the eight patents offered as additional reference serve to reinforce the applicant's assertion that the storage and retrieval of a PWM signal, or pattern representing a PWM signal, having stochastic characteristics results in an unpredicted or unexpected result with respect to prior art.

In each previous example, a sufficiently fast processor could execute the calculations in a short enough time, or the reference information could be generated from an analog signal sampled with an analog to digital converter. That is, the calculation times were predictable and time limited, whereas the delay processing required to modify a PWM signal to integrate stochastic information depends on the quality of the stochastic information and cannot be shortened if the delay is created in real-time. The look-up table for PWM signals having a stochastic characteristic provides an advantage for a system transacting in PWM signals having stochastic characteristics and that advantage is not available through alternate means.

In summary, the approaches to PWM signals having stochastic characteristics have traced a development path where, first, several advantages were associated with the method, second, difficulty with the delay in control, where a feedback signal was necessary, third, where higher frequencies were used to shorten the delay (surrendering some of the advantage of PWM signals having stochastic characteristics) and finally, where limits and compensation were applied to control the impact of the control delay. At the same time, the cost of storage and available storage capacity in small control devices have gone down and up respectively until the cost of storing a significant number of control patterns is small compared to the cost of other components of power transfer devices.

### SUMMARY OF INVENTION

The disclosed embodiments of the invention are directed to any of several methods that are used with a power transfer device wherein the basic pattern for a PWM control signal is provided with stochastic (random) characteristics and this signal is stored and retrieved to create an output waveform at a power transfer device.

In accordance with one embodiment of the invention, a system and method for generating a digital pulse width modulation (PWM) control signal for a power transfer device is disclosed that includes providing a digital PWM signal having a stochastic characteristic and control information, storing one or more related signals, and retrieving one or more stored digital PWM signal and applying these to determine the output of a power transfer device.

In accordance with another aspect of the foregoing embodiment, the provided PWM signals exhibit frequency domain characteristics of distributing one or more discrete frequency component energy among two or more discrete frequency components, distributing one or more discrete frequency component energy across portions of the continuous spectrum, distributing one or more peak densities of frequency energy from narrow segments of the continuous spectrum to wider segments of the continuous spectrum, redistributing frequency energy to segments of the frequency spectrum avoiding those portions of the spectrum that are associated with problems for power transfer devices, redistributing frequency energy and reshaping the final output waveform to intentionally compensate for pre-defined or desired harmonic components that are associated with desirable output characteristics for power transfer devices.

In accordance with another aspect of the foregoing embodiment, the provided PWM signals are configured to minimize at least one parameter from among harmonic signatures, is configured to minimize audible noise from the power transfer device, is configured to minimize component vibration in the power transfer device, is configured to reduce unnecessary switching events, is configured to reduce audible noise in power utilization equipment connected to the power transfer device, is configured to minimize component vibration in power utilization equipment connected to the power transfer device, or is configured to reduce frequency-domain energy peaks from current components in the power transfer device.

In accordance with another embodiment of the invention, a circuit is provided that includes circuitry or a computational system and software or a combination of both for generating a digital pulse width modulation (PWM) control signal for a power transfer device that includes software or a device such as a circuit that provides a digital PWM signal having stochastic characteristics and control information.

In accordance with another aspect of the foregoing circuit, the features described above with respect to the method are embodied in the circuit. This may be accomplished in hardware, software, firmware, or any combination of the foregoing.

For purposes of the description herein, stochastic as used herein includes the entire range of signal descriptions from an entirely random assignment of PWM timing events to a highly selective modification of purely deterministic PWM timing events; further including any method of creating these signals, including two examples, the first being a hand generated PWM signal (representing a waveform) that would fail to pass a mathematical test for randomness, but nevertheless blurs frequency components with respect to a standard PWM signal (representing a waveform), the second being a PWM signal or reference signal that has been selected from a collection of randomly created signals subsequently singled out and then repeated to obtain desired results.

In addition, a stochastic signal as used herein is intended to include a range of stochastic activity, ranging from the assignment of a random variable or variables to an aspect or aspects of a signal, to a handpicked, purposeful modification of an otherwise deterministic signal so that the signal exhibits one or more random or pseudo-random characteristics.

In accordance with another embodiment of the invention, an extension to these methods is provided where one or more of the PWM signals are stored, and one or more feedback signals are used to select from among stored digital PWM signals so that the resulting retrieved PWM control signal that exhibits stochastic characteristics can create an output waveform wherein the output waveform of a power transfer device acts as if fully controlled by the feedback signal.

A further extension to these methods, where a digital control program, the stored digital PWM signals, the interface with a power transfer device output circuit, and the interface with the power transfer device feedback circuit have all been folded into one active computer program, allows that the representation of the stored digital PWM signal may vary over a wide range of encoded patterns to suit the programming method at hand, and further, the stored pattern PWM signal may be subject to modification with respect to time slot allocation and time durations by the control program in order to allow for rapid adjustments to timing, that is, frequency, of the power transfer devices.

In accordance with another embodiment of the invention, the method for selecting among stored digital PWM signals may be any one or a combination of several methods, each based on sensing one or more feedback signals, for example, a computer algorithm may perform the selection via a mapping function, feedback ranges may be assigned to bins wherein bins are assigned to stored digital PWM signals, or feedback values may be mapped into matrix values wherein a range of matrix values causes selection of stored digital PWM signals.

In accordance with another embodiment of the invention, the method for providing digital PWM signals may be assigned to a time prior to the time a stored signal is used, for example, the stored signal may be provided during a previous cycle of the power waveform at the output of the power transfer device operation.

### BRIEF DESCRIPTION OF DRAWINGS

The foregoing and other features and advantages of the present invention will be more readily appreciated as the same become better understood from the following detailed description when taken in conjunction with the accompanying drawings, wherein:

FIG. 1 is a high-level block diagram of a Pulse Width Modulation (PWM) method, plus possible variations on the method, formed in accordance with the present invention;

FIG. 2 is a combination graph depicting one example of a control signal that might be used to create a sinusoidal waveform, with a representation of frequency domain results comparing PWM methods previously found in the art and a PWM control signal with stochastic characteristics that has been provided to approximate the same waveform;

FIG. 3 is a combination graph depicting one example of a control signal that might be used to create a sinusoidal waveform, with a representation of frequency domain results comparing PWM methods previously found in the art and a PWM control signal with stochastic characteristics that has been provided to approximate the same waveform; and

FIG. 4 is a combination graph depicting one example of a control signal that might be used to create a sinusoidal waveform, with a representation of frequency domain results comparing PWM methods previously found in the art and a PWM control signal with stochastic characteristics that has been provided to approximate the same waveform.

### DESCRIPTION OF EMBODIMENTS

Specifically, and with reference to FIG. 1, a standard deterministic PWM signal represents the waveform it will create as a portion of turn-on-time from moment to moment. On the other hand, a digital PWM waveform having stochastic characteristics can be generated via many methods, for example a deterministic PWM signal can be passed through a process that substantially matches the process identified in U.S. Pat. No. 6,510,068, wherein the output from that process has the stochastic characteristics of a spread frequency signature. Although the method component used to generate a digital PWM waveform having stochastic characteristics 101 is depicted as a computational algorithm it can also be a partially analog circuit as in the example using U.S. Pat. No. 6,510,068 above with a digital signal capture. The resulting digital PWM signal having stochastic characteristics 102 may be stored. Specifically, the resulting digital PWM signal having stochastic characteristics is mapped to a one of several possible storage representations in block 103. The mapped representation 104 is stored in a digital storage component 105. A retrieved signal 111 is used to drive a control component 120 of a power transfer device.

The present invention involves the use of a digital PWM signal with stochastic characteristics, which is subsequently used, in some cases after further time-base modification and in some cases without further modification, to carry control information to control the output of a power transfer device.

Power transfer devices are, in some cases, made to control single-phase power flow; in this case the invention is substantially represented as a single PWM control signal stream, for example, where a final control signal 150 is connected to a power-switching channel 151. In other cases, power transfer devices are made to control two- or three-phase power flow, for example, where two final control signals 170 are connected to two power-switching channels 171, or where three final control signals 180 are connected to three power-switching channels 181. In other cases, power transfer devices switched power flows in many pathways (e.g., six or twelve in harmonic power mitigation systems); in these cases the invention is substantially represented as one or more PWM control signal streams. In one embodiment of the present invention is substantially represented as a single PWM control signal stream where one or more final control signals 160 are connected to one or more digital to analog converters 161, where the analog output signals 162 are connected to one or more power-switching channels 163.

The disclosed embodiments of the present invention are operable in the digital domain, where signals are represented as streams of values that reflect time domain waveforms, in the digital domain where signals are represented as streams of values that reflect frequency (or wavelet) domain information, and in the analog domain where signals are represented as varying voltages that reflect time domain waveforms, or further where time domain waveforms are sampled and transferred as digital streams.

The following descriptions, coordinated with block diagrams of the method, are related to the digital domain. The implementation, in the analog domain, and especially where analog signals are used with digitally sampled signals, is accessible to practitioners of the art by extending the waveform descriptions (in cases where an analog waveform is plausible) from the digital domain to the analog domain.

There are several ways that this invention can be embodied to obtain similar advantages. Several are outlined herein. As will be readily appreciated from following description, the general order of the process and the resulting effect are among the novel characteristics of the invention.

Referring to FIG. 1, shown therein is a method comprised of a block 101 that generates a PWM waveform containing functional control information exhibiting stochastic characteristics, wherein, after encoding and storage one or more control signals are ready to be retrieved.

The control block 122 manages or translates a feedback signal 123 so that desired control components (e.g., timing and amplitude) are identified by its outbound interface 124. This control signal management is highly dependent on the application and specific characteristics of power switching elements and load characteristics of the power transfer device. Further, this control management is generally understood and executed by practitioners skilled in the art. The resulting outbound interface 124 may be defined to represent any of several control functions. For example, signals supplied by the outbound interface 124 might represent synchronization 130 (i.e., the timing of the desired power transfer device output waveform) and amplitude (i.e., the equivalent voltage level of the desired power transfer device output waveform) wherein a selection is made 125 from among the stored PWM waveform containing functional control information exhibiting stochastic characteristics and timing is used to adjust the frequency of the output, for example, by applying the synchronization 130 information to a timer control component 131 wherein the timer control component adjusts the length of time of each time-slot to accommodate a range of the fundamental frequency at the output of the power transfer device. The resulting outbound interface 124 may be defined to represent other combinations of control functions, for example current amplitude (i.e., the equivalent current level of the power transfer device output channel) wherein a selection is made 125 from among the stored PWM waveform containing functional control information exhibiting stochastic characteristics. The resulting outbound interface 124 may be defined to represent other combinations of control functions, for example harmonic current content (i.e., the equivalent current amplitude of harmonic current components in the power transfer device output channel) wherein a selection is made 125 from among the stored PWM waveform containing functional control information exhibiting stochastic characteristics, specifically to select a control signal that partially corrects for or further controls the harmonic current components. The resulting outbound interface 124 may be defined to represent other combinations of control functions associated with selecting form among stored signals.

The resulting outbound interface 124 may be defined to represent other combinations of control functions, wherein these functions are not required in the moment, for example, a digital representation of the power channel output 128 can represent an entire description of voltage, current, or voltage plus current wherein a computational algorithm can analyze the signal and prepare a responsive digital PWM waveform containing functional control information exhibiting stochastic characteristics, transferred 102 to an encoding scheme 103 and further transferred 104 to storage 105 to be available as a selected signal in subsequent power cycles. In this example, when a second feedback path is required the control block 126 manages or translates a feedback signal 127 connected to the outbound interface block 124.

The resulting outbound interface 124 may be defined to represent other combinations of control functions, wherein these functions are not required in the moment, for example, a digital representation of the power channel output 128 can represent an entire description of voltage, current, or voltage plus current wherein a computational algorithm performs analysis, and wherein the computational component generating digital PWM signals containing functional control information exhibiting stochastic characteristics is not coincident in space with the power transfer device switching component. For example, the digital representation 128 can be captured during a series of experiments with the power transfer device switching component and the analysis can be performed later, in preparation of a series of one or more digital PWM signals encoded and stored in the power transfer device switching component or in a similar, but separate, power transfer device switching component.

For purposes of clarity, the descriptions of the embodiments above utilize separate program modules to indicate sub-functions of the invention. In practice, the codification of these embodiments (e.g., a specific implementation in a programming language) is compact enough that it can be represented in a single algorithmic definition several pages in length. This allows one to conceptualize the implementation as a more compact, more closely integrated, program.

Conceptualizing the implementation as a more closely integrated program holds several implications for practitioners of the art. First, the means of encoding a PWM signal having stochastic characteristics for storage may include one or more of several options, including, for example, a list of state values (i.e., a value describing whether a pulse is on {as either a positive or negative pulse} or off), or, for example, a list of transition times.

The form of the invention and the characteristics of control following from the invention are related, in addition to other components of the invention, to characteristics of any one of several possible comparative waveforms that are designed to optimize multiple parameters of power transfer waveforms so that a final power transfer waveform created by a PWM signal is optimized for use in a power transfer application. A comparative waveform is a pattern that has been developed, or partially developed, and stored with the specific purpose of minimizing harmonic signatures, minimizing perceived audio components, minimizing vibration, enhancing power transfer, and creating a predictable and reliable waveform.

The creation, temporary storage, analysis, tuning, and final storage of a series of comparative waveforms, ultimately resulting in a best signal model (aka signal replica) is one result and a benefit of the invention described herein. A fully developed comparative waveform (to be stored as a signal replica) would, for example, appear as the signal 104 delivered by 103 in FIG. 1.

In accordance with another aspect of the invention one characteristic of control is enhanced by minimizing the processing time required to respond to feedback control signals by segregating the creation (and storage) of a comparative waveform (aka signal replica) from the operations on the comparative waveform required by the feedback signal. For example, the interaction of the timer control component 131 in FIG. 1 with the assignment of output 121 only requires slot assignment time (which can be very short relative to 60 hertz systems) and activation of the next time slot. To further this example, the retrieved PWM waveform may be “advanced” relative to the intended output waveform, using the feedback control to make adjustments based on the just-previous value of the control Information. This allows the PWM output to track to as short a time as the time between one or two time slices of the stored waveform, while embodying a delay in responsiveness of the control signal of only a few time slices.

In accordance with a further aspect of the invention, the quality of power transfer device output is enhanced by allowing the comparative waveform to undergo frequency domain analysis, power spectrum analysis, impulse analysis, resonance analysis, or wavelet component analysis, whichever are most appropriate to a specific power transfer device.

FIG. 2 is a combination graph depicting one example of a control signal that might be used to create a sinusoidal waveform, with a representation of frequency domain results comparing a PWM methods previously found in the art and a PWM control signal with stochastic characteristics that has been provided to approximate the same waveform. The frequency domain image is anchored on the left by the fundamental power frequency (typically 60 Hz in the United States). The fundamental frequency image in the deterministic PWM control method 200 is shown at approximately 70 percent of the maximum value available without distorting the voltage waveform as related to the typical circumstance where a battery or DC supply voltage is used as a source for the power switching channel. In this example, the fundamental frequency image for the PWM signal exhibiting stochastic characteristics 201 is substantially the same as 200, shown at approximately 70 percent of the maximum value available without distorting the voltage waveform. The deterministic PWM control method is the result of approximately 13 pulses in each half-cycle of the fundamental sinusoidal waveform. The frequency image at the 25^{th} harmonic 202 is a typical image for a Fourier transform of a digital PWM signal. The frequency image at the 49^{th} harmonic 203 is also a typical image for a Fourier transform of a digital PWM signal. In this diagram the darker lines are associated with the deterministic PWM waveform.

In the example in FIG. 2, the magnitude of frequency image components for a PWM signal exhibiting stochastic characteristics 204, 205, and others, is shown with a thin line including the shape of an oval. The height of the oval compares directly to the height of the frequency component images of the deterministic PWM method, while the phase angle of frequency image components for a PWM signal having stochastic characteristics is shown by the relative turning about the arc represented as a circle set in a single-point perspective view. The oval and frequency component images are represented with thinner lines.

The example shown in FIG. 2 stems from the use of a ramp waveform 206 used as a reference with a sinusoidal waveform 207 to represent pulses for the PWM waveform. For fundamental waveforms with amplitude less than or about 95 percent of maximum, the PWM signal having stochastic characteristics will include 13 pulses, matching the comparative deterministic PWM method. This is a substantially low switching rate for PWM power systems.

The digital control waveform used for the example in FIG. 2 is developed by running many alternative possibilities and selecting the best few based on numerical analysis. Further, the best images are selected for graphical analysis. One of these, numbered 799078 at the associated radio button 208, is selected from approximately 1,000,000 trials.

In practice, the upper and lower portions of a power waveform are often produced through two distinct pathways of circuiting in a power transfer device; this requires one or more separate control waveforms for each pathway of power circuiting. The control waveform is depicted here as one waveform to facilitate frequency domain analysis. The graph depicts the use of 13 pulses to create each half-cycle; in practice the number of pulses used varies and is often greater. The waveform is depicted here with 13 pulses in each half-cycle because the use of fewer pulses exaggerates the problems depicted at lower harmonic numbers in the frequency domain analysis.

Continuing the example, FIG. 3 depicts a similar representation as in FIG. 2, except the waveforms are shown at approximately 90 percent of the maximum value available without distorting the voltage waveform. Drawing item numbers 300, 301, 302, 303, 304, 305, 306, 307, and 308 are similar to drawing item numbers 200, 201, 202, 203, 204, 205, 206, 207, and 208 in FIG. 2. The radio button representing 90 percent 309 is moved to represent the difference in amplitudes.

Continuing the example, FIG. 4 depicts a similar representation as in FIG. 2, except the waveforms are shown at approximately 110 percent of the maximum value available without distorting the voltage waveform, that is, this output waveform is distorted. Drawing item numbers 400, 401, 402, 403, 404, 405, 406, 407, and 408 are similar to drawing item numbers 200, 201, 202, 203, 204, 205, 206, 207, and 208 in FIG. 2. The radio button 409 representing 110 percent is moved to represent the difference in amplitudes. In this example, at 110 percent of the maximum amplitude, the waveforms are distorted at the 3^{rd} and 5^{th} harmonics 410, 411, which is consistent with the expected distortion when a sinusoidal waveform is limited with respect to peak values.

In a different example, a PWM signal exhibiting stochastic characteristics is selected from over twenty sets of hand crafted delay patterns. The code fragment below represents the delay pattern applied to an original PWM control waveform. This delay pattern is repeated each half-cycle. The delay pattern includes 17 pairs of numbers, each pair applied to the pair of turn-on and turn-off transitions that make one pulse in the control signal.

; hand selected pattern number 14
(define random-delay-source-list
‘(9 9 11 11 1 1 19 19 6 6 14 14 9 9 11 11 10 10 11 11 9 9 14 14 6 6 19
19 1 1 12 12 8 8))

The code fragment above is based on the Scheme dialect of Lisp. The fragment indicates the assignment of delay values (represented in clock segments). Scheme is used here to demonstrate values for this example; in practice any one of many programming languages are used to define control waveforms and to accomplish waveform analysis.

To complete the example started above, the list of delay values was selected from over twenty lists that were designed to meet specific goals. Even so, the frequency-domain graph representing the resulting control waveform includes significant energy in lower harmonics. In practice, energy included in lower harmonics of power transfer devices is undesirable.

In one implementation, the present invention reduces residual harmonic components by facilitating hand-selected bits to be added or removed from a stored comparative waveform, in effect modifying the transition times of one comparative waveform to create a modified comparative waveform. Hand-selecting bits can include adding and removing bits to match specific targets of voltage or energy part sums based on normalized power transfer algorithms. In another aspect of the implementation, hand-selecting bits includes adding and removing bits to match specific targets of frequency domain or power spectrum part sums based on sophisticated power transfer algorithms. Sophisticated power transfer algorithms include, among other possible implementations, a displacement algorithm wherein one or more individual pulses are moved in time and then adjusted in duration to minimize the impact on lower numbered harmonics. And in accordance with a further aspect of the implementation, hand-selecting bits includes trading bits across spectrum locations based on balancing multiple functional tradeoffs in power transfer output waveforms. The present invention provides the ability to enhance the design of power transfer waveforms through, among other features, the ability to concurrently define both shifts in timing and shifts in duration of PWM pulses in creating comparative waveforms. In other words, the PWM waveform is modified by shifting the timing and by altering the duration of the pulse within the same pulse.

In another example; the basic control waveform is defined using a collection of state values (i.e., a value describing whether a pulse is on {as either a positive or negative pulse} or off) as listed below; with 1 representing ‘on’ and 0 representing ‘off’.

```
(define about-eight-cycles-basic-control-waveform
  (lambda ( )
  (let ((list-of-values ‘( ))
```

(seed-list-1
‘(0 0 0 0 0 0 0 0 0 0 0 0 0 0 0 0 0 0 0 0 0 0 0 0 0 0 0 0 0 1 1

0 0 0 0 0 0 0 0 0 0 0 0 0 0 0 0 0 0 0 0 0 0 0 0 0 0 0 0 0 0
0 0 0 0 0 0 0 0 0 0 0 0 0 0 0 0 0 0 0 0 0 0 0 0 0 1 1 1 1 1
1 1 1 1 1 0 0 0 0 0 0 0 0 0 0 0 0 0 0 0 0 0 0 0 0 0 0 0 0 0
0 0 0 0 0 0 0 0 0 0 0 0 0 0 0 0 0 0 0 1 1 1 1 1 1 1 1 1 1 1
1 1 1 1 1 1 1 1 1 1 0 0 0 0 0 0 0 0 0 0 0 0 0 0 0 0 0 0 0 0
0 0 0 0 0 0 0 0 0 0 0 0 0 0 0 1 1 1 1 1 1 1 1 1 1 1 1 1 1 1
1 1 1 1 1 1 1 1 1 1 1 1 1 1 1 0 0 0 0 0 0 0 0 0 0 0 0 0 0 0
0 0 0 0 0 0 0 0 0 0 0 1 1 1 1 1 1 1 1 1 1 1 1 1 1 1 1 1 1 1 1
1 1 1 1 1 1 1 1 1 1 1 1 1 1 1 1 1 1 0 0 0 0 0 0 0 0 0 0 0 0
0 0 0 0 0 0 0 0 1 1 1 1 1 1 1 1 1 1 1 1 1 1 1 1 1 1 1 1 1 1
1 1 1 1 1 1 1 1 1 1 1 1 1 1 1 1 1 1 1 1 1 1 1 1 0 0 0 0 0 0
0 0 0 0 0 0 0 1 1 1 1 1 1 1 1 1 1 1 1 1 1 1 1 1 1 1 1 1 1 1
1 1 1 1 1 1 1 1 1 1 1 1 1 1 1 1 1 1 1 1 1 1 0 0 0 0 0 0 0 0
0 0 0 0 1 1 1 1 1 1 1 1 1 1 1 1 1 1 1 1 1 1 1 1 1 1 1 1 1 1
1 1 1 1 1 1 1 1 1 1 1 1 1 1 1 1 1 1 1 1 1 1 1 1 1 1 1 0 0 0
0 0 0 0 0 0 1 1 1 1 1 1 1 1 1 1 1 1 1 1 1 1 1 1 1 1 1 1 1 1
)

```
  )
(seed-list-2
  ‘(1 1 1 1 1 1 1 1 1 1 1 1 1 1 1 1 1 1 1 1 1 1 1 1 0 0 0 0 0 0 0
```

0 0 0 0 1 1 1 1 1 1 1 1 1 1 1 1 1 1 1 1 1 1 1 1 1 1 1 1 1 1
1 1 1 1 1 1 1 1 1 1 1 1 1 1 1 1 1 1 1 1 1 1 1 1 1 0 0 0 0 0
0 0 0 0 0 0 0 0 1 1 1 1 1 1 1 1 1 1 1 1 1 1 1 1 1 1 1 1 1 1
1 1 1 1 1 1 1 1 1 1 1 1 1 1 1 1 1 1 1 1 1 1 1 1 0 0 0 0 0 0
0 0 0 0 0 0 0 0 0 0 1 1 1 1 1 1 1 1 1 1 1 1 1 1 1 1 1 1 1 1
1 1 1 1 1 1 1 1 1 1 1 1 1 1 1 1 1 1 1 1 1 0 0 0 0 0 0 0 0 0
0 0 0 0 0 0 0 0 0 0 0 0 1 1 1 1 1 1 1 1 1 1 1 1 1 1 1 1 1 1
1 1 1 1 1 1 1 1 1 1 1 1 1 1 1 1 1 1 1 1 0 0 0 0 0 0 0 0 0 0 0
0 0 0 0 0 0 0 0 0 0 0 0 0 0 0 1 1 1 1 1 1 1 1 1 1 1 1 1 1 1
1 1 1 1 1 1 1 1 1 1 1 1 1 1 0 0 0 0 0 0 0 0 0 0 0 0 0 0 0 0
0 0 0 0 0 0 0 0 0 0 0 0 0 0 0 0 0 0 1 1 1 1 1 1 1 1 1 1 1 1
1 1 1 1 1 1 1 1 1 1 1 1 1 0 0 0 0 0 0 0 0 0 0 0 0 0 0 0 0 0
0 0 0 0 0 0 0 0 0 0 0 0 0 0 0 0 0 0 0 0 0 0 0 1 1 1 1 1 1 1
1 1 1 1 1 1 1 0 0 0 0 0 0 0 0 0 0 0 0 0 0 0 0 0 0 0 0 0 0 0
0 0 0 0 0 0 0 0 0 0 0 0 0 0 0 0 0 0 0 0 0 0 0 0 0 0 0 1 1 1
1 1 1 1 1 0 0 0 0 0 0 0 0 0 0 0 0 0 0 0 0 0 0 0 0 0 0 0 0 0
)

))

```
(do
    ((number-of-cycles 0 (+ 1 number-of-cycles)))
  ((> number-of-cycles 7) list-of-values)
  (begin
    (set! list-of-values (append list-of-values seed-list-2))
    (set! list-of-values (append list-of-values (trade-values seed-list-1)))
    (set! list-of-values (append list-of-values (trade-values seed-list-2))))
    (set! list-of-values (append list-of-values seed-list-1))
    )
  )))
```

The code fragment above is based on the Scheme dialect of Lisp. The fragment indicates the assignment of state values to create a list representing a basic control waveform. Scheme is used here to demonstrate values for this example; in practice any one of many programming languages are used to define control waveforms and to accomplish waveform analysis. In the fragment above, the program-defined function named “(trade-values <seed-list>)” is used to assign a value of “−1” in the place of each value “1” as needed to represent the negative half-cycle of sinusoidal waveforms with a PWM control signal.

Continuing this example, each string of l's in a row represent one pulse and operations on these pulses occur by transitioning pulse-edge 0's to 1's or pulse-edge 1's to 0's in order to widen or narrow each pulse respectively. This basic pattern is nearly the same pattern as would be obtained by mathematically creating a theoretical cosine wave using previous art PWM methods.

Continuing this example, similar to the definition of the basic control waveform, the modified control waveform is defined using a collection of state values (i.e., a value describing whether a pulse is on {as either a positive or negative pulse} or off) as listed below; with 1 representing ‘on’ and 0 representing ‘off’.

```
(define about-eight-cycles-modified-control-waveform
  (lambda ( )
  (let ((list-of-values ‘( ))
```

(seed-list
‘(0 0 0 0 0 0 0 0 0 0 0 0 0 0 0 0 0 0 0 0 0 0 0 0 0 0 0 0 0 0 0

0 0 0 0 0 0 0 0 0 0 0 0 0 0 0 0 0 0 0 0 0 0 1 1 1 1 1 1 1 0
0 0 0 0 0 0 0 0 0 0 0 0 0 0 0 0 0 0 0 0 0 0 0 0 0 0 0 0 0 0
0 0 0 0 0 1 1 1 1 1 1 1 1 1 1 1 1 1 0 0 0 0 0 0 0 0 0 0 0 0
0 0 0 0 0 0 0 0 0 0 0 0 0 0 0 0 0 0 0 0 0 0 0 0 0 1 1 1 1 1
1 1 1 1 1 1 1 1 1 1 1 1 0 0 0 0 0 0 0 0 0 0 0 0 0 0 0 0 0 0
0 0 0 0 0 0 0 1 1 1 1 1 1 1 1 1 1 1 1 1 1 1 1 1 1 1 1 1 1 0
0 0 0 0 0 0 0 0 0 0 0 0 0 0 0 0 0 0 0 0 0 1 1 1 1 1 1 1 1 1
1 1 1 1 1 1 1 1 1 1 1 1 1 1 1 1 1 1 1 1 1 1 1 1 1 1 1 1 1 0 0
0 0 0 0 0 0 0 0 0 0 0 0 0 0 0 0 0 0 0 0 1 1 1 1 1 1 1 1 1 1
1 1 1 1 1 1 1 1 1 1 1 1 1 1 1 1 1 1 1 0 0 0 0 0 0 0 0 0 0 0
0 0 0 0 0 0 0 0 0 0 1 1 1 1 1 1 1 1 1 1 1 1 1 1 1 1 1 1 1 1
1 1 1 1 1 1 1 1 1 1 1 1 1 1 1 1 1 1 1 1 1 1 1 1 1 1 1 1 1 0
0 0 0 0 0 0 0 0 0 0 0 0 0 0 0 1 1 1 1 1 1 1 1 1 1 1 1 1 1 1
1 1 1 1 1 1 1 1 1 1 1 1 1 1 1 1 1 1 1 1 1 1 1 1 1 1 1 1 1 1
1 1 1 1 1 1 1 1 1 1 1 1 1 0 0 0 0 0 0 0 0 0 0 0 0 0 1 1 1 1
1 1 1 1 1 1 1 1 1 1 1 1 1 1 1 1 1 1 1 1 1 1 1 1 1 1 1 1 1 1
)

))

(do

((number-of-cycles 0 (+ 1 number-of-cycles)))

```
  ((> number-of-cycles 7) list-of-values)
  (begin
```

(set! list-of-values (append list-of-values (reverse seed-list)))
(set! list-of-values (append list-of-values
(trade-values seed-list)))
(set! list-of-values (append list-of-values (trade-values (reverse

seed-list)))))

(set! list-of-values (append list-of-values seed-list))
)
)))

The code fragment above is based on the Scheme dialect of Lisp. The fragment indicates the assignment of state values to create a list representing a modified control waveform. Scheme is used here to demonstrate values for this example; in practice any one of many programming languages are used to define control waveforms and to accomplish waveform analysis. In the fragment above, the program-defined function named “(trade-values <seed-list>)” is used to assign a value of “−1” in the place of each value “1” as needed to represent the negative half-cycle of sinusoidal waveforms with a PWM control signal.

Continuing this example, each string of 1's in a row represent one pulse and operations on these pulses occur by transitioning pulse-edge 0's to 1's or pulse-edge 1's to 0's in order to widen or narrow each pulse respectively. This modified pattern would not be obtained by mathematically creating a theoretical cosine wave using previous art PWM methods; instead, it is created by hand placing state values in order to create desired results that are consistent with power transfer device operation. In this particular example, the goals set out for the modified control waveform included reduction of the 3^{rd}, 5^{th}, 7^{th} and 9^{th} harmonic components, and the reduction of the 17^{th} harmonic component, similar to the 17^{th} harmonic component 812 that is prominent in the frequency-domain analysis of the basic control waveform. Further, both the pulses and the spaces between pulses are defined to consistently respect a minimum number of state slots (seven) so as to allow for a range of future control feedback with minimum impact on control signal characteristics.

Finally, the modified control waveform is developed using 17 pulses in each half-cycle, identical to the basic control waveform shown in this example. Both the real component and the imaginary component are substantially free of harmonic components up to and including the 11^{th} harmonic and the 17^{th} harmonic is substantially eliminated. Instead, other harmonic components are prevalent. In practice, it is a matter of many trade-offs between PWM frequency, harmonic component values, and control scheme selection; but this example demonstrates both the ability to analyze a stored waveform so as to modify that waveform to match specific goals, and the ability to modify the way frequency components are allocated through the variation of both pulse location and width.

An additional brief example demonstrates an alternative means for creating a range of control patterns that can be packed into storage wherein the control step representing selection of a PWM value is accomplished with a comparison of digital values where one value is retrieved from a “time slot” and compared to a fixed value that further relates to an amplitude level of an output waveform.

This example is based on the notion that each collection of “on” and “off” states in a PWM pattern is tied to an output level of the power transfer device. In a DC to AC converter, a sinusoidal voltage waveform established so its peak voltage is approximately 90 percent of the DC bus voltage will exhibit approximately 57.3 percent of “on” states in an ideal circuit or a circuit at very low power loads. This is, for example, about 1173 slots “on” out of 2048 slots. In the same converter, the sinusoidal voltage waveform established so its peak voltage is approximately 92 percent of the DC bus voltage will exhibit approximately 58.6 percent of “on” states in an ideal circuit or a circuit at very low power loads. This is, for example, about 1199 slots “on” out of 2048 slots. Thus, if a digital PWM signal having a stochastic characteristic is know at a 90 percent peak value, a second digital PWM signal having a stochastic characteristic can be found with a 92 percent peak value by selecting approximately 26 additional “on” slots.

In this example, the additional “on” slots are added in groups of four by assessing the stochastic characteristic of each reasonable addition where a reasonable addition is defined to augment a pulse without causing another switching event in the digital PWM signal. The sample code essentially checks each available “on” slot in one-quarter cycle, adjacent to a previously defined “on” slot, analyzes the stochastic qualities of that addition, and selects one addition from the reasonable possibilities based on a measurement criteria. In pseudo-code:

```
(define (run-improvements)
  (for ((run-number (in-range 1 540)))
  (vector-copy! working-edge-array 0 blank-working-edge-array)
  (set-edges! (− starting-compare-value (* 8 run-number)))
  (set-metric-values! (− starting-compare-value (* 8 run-number)))
  (update-td-array! (best-position?)
    (− starting-compare-value (* 8 run-number)))
  ))
```

In the code fragment, “(update-td-array! . . . )” uses the best possible incremental result and modifies an array defined (i.e., scoped) outside the “run-improvements” function.

The resulting listing of numbers, for example, representing two pulses could look like this:

#(0 0 0 0 0 0 0 0 0 0 0 0 0 0 0 0 0 0 0 0 0 0 0 0 0 0 0 0 0 0 0 0 0 0 0 0 0 0 0 0
0 0 0 0 0 8272 13160 17944 19192 19192 19192 19192 19192 19192 19192
19192 18568 17632 16592 15656 14720 13888 13056 12224 11392 10664 9832
9104 8376 7752 7024 0 0 0 0 0 0 0 0 0 0 0 0 0 0 0 0 0 0 0 0 0 0 0 0 0 0 0 0 0 0 0 0
0 0 0 0 0 0 0 0 0 0 0 0 0 0 0 0 0 0 0 0 0 0 0 0 0 0 0 0 0 0 0 0 0 0 0 0 0 0 0 0 0 0 0 0
0 0 0 0 0 0 0 0 0 0 0 0 0 0 0 0 0 0 0 0 0 0 0 0 0 0 0 0 0 0 0 0 0 0 0 0 0 0 0 0 0 0 0 0
0 0 0 0 0 0 0 0 0 0 0 0 0 0 0 0 0 0 0 0 0 0 0 0 0 0 0 0 0 0 0 0 0 0 0 0 0 0 0 0 0 0 0
6608 7440 8376 9312 10248 11080 12016 12848 13784 14616 15448 16384
17216 18048 18880 19192 19192 19192 19192 19192 19192 19192 19192 19192
19192 19192 19192 19192 19192 19192 19192 19192 19192 19192 19192 19192
19192 19192 19192 19192 19192 19192 19192 19192 19192 19192 19192 19192
19192 19192 19192 19192 19192 19192 19192 19192 18984 18776 18568 18360
18048 17840 17632 17424 17216 17008 16800 16592 16384 16176 15968 15864
15656 15448 15240 15032 14824 14616 14408 14200 14096 13888 13680 13472
13264 13160 12952 12744 12536 12432 12224 12016 11912 11704 11496 11288
11184 10976 10768 10664 10456 10352 10144 9936 9832 9624 9520 9312 9104
9000 8792 8688 8480 8376 8168 8064 7856 7752 7544 7440 7232 7128 6920
6816 6712 6504 0 0 0 0 0 0 0 0 0 0 0 0 0 ... )

This example above is a partial list, representing approximately 4 of the 52 pulse edges in a full-cycle PWM signal example.

In this example, the selection process required for retrieving an individual digital PWM signal is a comparison of the integer in each slot against a reference integer that has been established for each output level represented in the list or array. For example, in the list above, a reference of 13000 would return a PWM waveform about mid-range of the limits established of output levels represented. Each individual time slot in an application, and in the analysis program, is defined as “on or “off” by a numerical comparison. In pseudo-code:

(if (> (vector-ref working-td-array td-position) (− compare-value 8))
(set! PDF-image-this-position “on”))

The pseudo-code fragment above is similar to the Scheme dialect of Lisp. The pseudo-code identifies array components representing PWM signal components.

An additional brief example demonstrates another alternative method for creating a range of control patterns that can be packed into storage wherein the control step representing selection of a PWM value is accomplished with a comparison of digital values where one value is retrieved from a “time slot”, or where a multi-dimensional array is constructed with a multiplicity of digital PWM signals.

In this example, a ramp image is created using a selection set of random numbers, subsequently used to determine the slope of each side of each ramp, and the ramp is used as if in an analog comparator circuit to define the values in PWM signal time slots.

```
(define (generate-best-wave-map-files starting-key-number)
  (for ((this-map-number (in-range 0 10000)))
    (let* (
      (fdArray #(1 2 3 4 5))
      (harmonics-sum 0)
      (this-ramp-seed (fill-ramp-seed
          (map-a-list-of-divisors list-of-primes)
          (map-a-list-of-divisors list-of-primes)))
      (layered-wave-map (make-layered-wave-map this-ramp-seed))
      (file-name-key (+ starting-key-number this-map-number))
      )
    ; (write layered-wave-map)
    (set! ramp-map-test (vector-append layered-wave-map
```

layered-wave-map))

```
    ; (write ramp-map-test)
    (set! working-td-array ramp-map-test)
    (set! compare-value (get-reference-number 0.90 ramp-map-test))
    (displayIn compare-value)
    (set! fdArray (return-frequency-domain-array compare-value))
    ; (displayIn fdArray)
    (set! harmonics-sum (odd-harmonics-81-cube-weighted
    fdArray))
    (displayIn harmonics-sum)
    (if (< harmonics-sum (* 1.03 best-result-so-far))
        (save-files-re-wave-map file-name-key ramp-map-test this-
```

ramp-seed harmonics-sum)

```
      #t)
    (if (< harmonics-sum best-result-so-far)
        (set! best-result-so-far harmonics-sum)
      #t)
    )))
```

The stochastic quality test used above, for this example, is expanded below. It is one possible quality test of many useful quality tests. This example quality test relies on a Digital Fourier Transform (DFT), further weighted to favor reducing individual frequency components. In particular, the quality test measures the energy in each of the odd harmonic components, as related to the fundamental frequency of the power transfer device, and further weighs the results, allowing higher frequencies a smaller impact on the resulting number. Then, this result is used to rank the quality of a particular trial. In pseudo-code:

```
(define (odd-harmonics-81-cube-weighted
      frequency-domain-array)
  (let ((local-sum 0+0i))
  (for ((harmonic-number (in-range 3 82 2)))
    (set! local-sum
        (+ local-sum
          (/ (expt
            (magnitude
              (vector-ref frequency-domain-array harmonic-number))
            3) harmonic-number)))
        )
        (/ local-sum 40)
    ))
```

The pseudo-code fragment above is similar to the Scheme dialect of Lisp. The pseudo-code, for example, indicates the use of a weighted sum of power harmonics from 3 to 81.

In practice, over 1,000,000 randomly generated trials were run to capture perhaps 2-dozen highly effective PWM signal patterns.

In practice, the results of one series of trials can be used to describe a collection of values based on a ramp, or a separate set of trials can be run to manufacture a small range of output values. For example, a peak waveform level of between 88 and 92 percent might result from the best selection of one set of trials while a peak waveform level of between 83 and 87 percent might result from the best selection of a second set of trials. Conversely, an individual PWM signal image representing a single output level can be stored as a collection of “1” and “0” values, each based on the best selection of one set of trials. This collection of individual PWM signal images can be represented as an array.

The stochastic quality test is highly versatile. It is not necessary to compare the result to a strict sinusoidal waveform (i.e., as implied by using an Digital Fourier Transform analysis). Instead, it is possible to insert into the Digital Fourier Transform calculation desired waveform components, for example, a small negative 3^{rd} harmonic and smaller positive 5^{th} harmonic, as targets for the final waveform. This has the effect of shaping the desired output waveform at the power transfer device.

The stochastic quality test is not limited to theoretical analysis. Instead, for example, it is possible to measure the output of a power transfer device under load conditions, run trials based on the examples above, capturing actual measurements as the stochastic quality test.

Although the examples above demonstrate the utilization of fixed width state slots (e.g., 2048 slots per cycle at a fixed frequency) and the ability to reserve a fixed number of state slots to facilitate control, in another implementation of the invention the control scheme may utilize a continuously variable adjustment to pulse widths that are otherwise stored as fixed width state slots.

In another implementation of the invention the state slots may be modified in real time to make adjustments of the fundamental frequency (e.g., the fundamental frequency of the power transfer device output), and further, the control scheme may utilize a continuously variable adjustment to pulse widths.

When the present invention is implemented in a power transfer device, it enhances the response of the power transfer device to changing harmonic loads by allowing a collection of comparative waveforms, each one responsive to different harmonic load requirements, to be designed, analyzed, stored, and modified or selected by a feedback circuit within a particular power transfer device.

The present invention also enhances the capability of circuit designers to design an ideal waveform by supporting the investigation of many algorithms, both formal and informal, in order to create the appearance of stochastic frequency signatures in the comparative waveform. Such algorithms can include a circular series of offsets created by a series of hand-selected numbers, or an algorithm that includes a series of numeric offsets created by a modulo operation on a hand-selected base number, or algorithms having a series of balanced offsets (i.e., large and small, or early and late), and algorithms having a series of numbers selected from a tested collection of multiple lists created by repeating the results of a programmed numeric processor providing randomly generated lists of numbers, wherein, in each case above, the offsets and lists of numbers are subsequently used to define the transition times of a comparative waveform.

The present invention in another implementation enhances the capability of circuit designers to design an ideal PWM control waveform by supporting the investigation of sophisticated power transfer algorithms in order to create the appearance of stochastic frequency signatures and, at the same time, minimize the residual energy found in the lower numbered harmonics of the power transfer waveform as controlled by the comparative waveform. Sophisticated power transfer algorithms include a displacement algorithm wherein each individual pulse is moved in time and then adjusted in duration to minimize its impact on lower numbered harmonics, a paired pulse displacement algorithm wherein two individual pulses are moved in time and then one pulse of the two is adjusted in duration to minimize the combined impact on lower numbered harmonics, a power transfer algorithm having combinations where one or more pulses are subjected to a displacement algorithm with a correction pulse in a series of pulses where each group may independently include one or more pulses.

The present invention also provides, in part, the ability to enhance the capability of circuit designers to design an ideal PWM control waveform by supporting the investigation of sophisticated power transfer algorithms in order to create the appearance of stochastic frequency signatures and, at the same time, minimize the residual energy found in the lower numbered harmonics of the power transfer waveform as controlled by the comparative waveform. This investigation includes investigation into the timing characteristics defined by the orthogonal relationships of lower numbered harmonics, especially harmonics that a circuit designer is trying to eliminate, investigating refinement of the comparative waveform master clock frequency (e.g., defining the requirements of the Time Mark shown in FIG. 5) by analyzing the frequency requirement of the uppermost two or uppermost three harmonics from the set of harmonics that a circuit designer is trying to eliminate, investigation of non-uniform time division assignment based on overlaying harmonic signals, and investigation that involves detailed analysis of changes made to comparative signals by hand-selecting bits (e.g., hand selecting state values). In each case, the investigation is facilitated as a study of patterns and detailed analysis (not in real time) and as the study of applied patterns to test specific cases in power transfer devices in laboratory conditions (in real time).

The implementation of the present invention enhances the capability of circuit designers to apply waveform improvements to a broad range of circumstances requiring adjustment of the fundamental frequency of the power transfer waveform. These circumstances include maintaining a fundamental PWM frequency based on power transfer device filtering design limitations and storing multiple images of the comparative waveform (aka multiple signal replicas) such that each may be selected and smoothly modified within the limitations of a master clock Time Mark. These circumstances can also include maintaining a PWM pattern (a patterned comparative waveform) such that the patterned signal (aka signal replica) may be smoothly modified by varying the time basis of the master time clock thereby maintaining the same number of Time Marks during each fundamental frequency cycle even as the fundamental frequency varies.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A method for generating a pulse width modulation (PWM) control signal for a power transfer device, comprising:
providing a digital PWM signal having stochastic characteristics and control information by combining control pattern information with stochastic information, wherein at least one control pattern embodied in the digital PWM signal can determine an output of the power transfer device; and
storing one or more of the digital PWM signals in a digital storage device so as to allow the digital PWM signals to control the output of the power transfer device wherein retrieving one or more digital PWM signals from the stored digital PWM signals is a control step.

2. The method of claim 1 further comprising providing a digital PWM signal having stochastic characteristics and control information wherein the digital PWM signal embodies one or more characteristics in regard to the power transfer device output.

3. The method of claim 2 wherein one or more provided digital PWM signals are configured to minimize at least one parameter from among harmonic parameters, is configured to minimize audible noise from the power transfer device, is configured to minimize component vibration in the power transfer device, is configured to reduce unnecessary switching events, is configured to reduce audible noise in power utilization equipment connected to the power transfer device, is configured to minimize component vibration in power utilization equipment connected to the power transfer device, or is configured to reduce frequency-domain energy peaks from current components in the power transfer device.

4. The method of claim 2 wherein one or more provided digital PWM signals embody at least one from among: (a) a distribution of one or more discrete frequency component energies among two or more discrete frequency components, (b) a distribution of energy from at least one discrete frequency component across portions of the continuous spectrum, (c) a distribution of one or more peak densities of frequency energy from narrow segments of the continuous spectrum to wider segments of the continuous spectrum, (d) a distribution of deterministic frequency signatures and stochastic frequency signatures exhibited in the frequency domain, (e) a redistribution of frequency energy to segments of the frequency spectrum that avoid those portions of the spectrum that are unsuitable for the power transfer device, and (f) a redistribution of frequency energy and a reshaping of an output waveform to compensate for harmonic components in the output waveform.

5. The method of claim 2 wherein one or more provided digital PWM signals are created, at least in part, by hand coding a digital PWM signal representation.

6. The method of claim 2 wherein one or more provided digital PWM signals are created, at least in part, by calculating an incremental change based on a similar digital PWM signal representation.

7. The method of claim 2 wherein one or more provided digital PWM signals are created, at least in part, by defining two or more digital PWM signal representations and selecting among the representations by measuring the best representation in regard to the power transfer device output.

8. The method of claim 2 wherein one or more provided digital PWM signals are created, at least in part, by deriving through calculation an ideal digital PWM signal representation.

9. The method of claim 1 wherein selecting from among two or more stored digital PWM signals is a control step.

10. The method of claim 9 wherein selecting from among two or more stored digital PWM signals further comprises sensing one or more feedback signals associated with the power transfer device and utilizing an algorithm to select from among stored digital PWM signals.

11. The method of claim 9 wherein selecting from among two or more stored digital signals further comprises sensing one or more feedback signals associated with the power transfer device and assigning a bin value wherein the bin value causes selection and utilization of one or more of the stored digital PWM signals.

12. The method of claim 9 wherein selecting from among two or more stored digital signals further comprises sensing one or more feedback signals associated with the power transfer device and assigning values in a matrix wherein a range of matrix values relate to selection and utilization of one or more of the stored digital PWM signals.

13. The method of claim 1 wherein the stored digital PWM signals are encoded, packed, or organized in regard to storage capacity and retrieval speed.

14. The method of claim 13 wherein the stored digital PWM signals are encoded or packed as a series of increasing integer values so that one list or array encodes the values for multiple levels of output of the power transfer device.

15. The method of claim 13 wherein the stored digital PWM signals are stored as a series of “1” and “0” values relating to PWM control values in specific time slots.

16. The method of claim 13 wherein the stored digital PWM signals are stored as a series of multi-dimensional arrays or matrices where selecting from among two or more stored digital PWM signals is equivalent to pointing to a specific dimension in an array or matrix.

17. The method of claim 1, further comprising at least one modification of the stored digital PWM signal performed at the power transfer device to allow the stretching of time slots across different time bases, that is, to allow a single stored PWM signal to serve a range of output frequencies of the power transfer device.

18. The method of claim 1 wherein one or more retrieved digital PWM signals is converted to one or more analog PWM signals in the power transfer device.

19. The method of claim 1 wherein one or more retrieved digital PWM signals are used to determine the output of two or more power channels in the power transfer device.

20. The method of claim 1 wherein one or more retrieved signals are used to determine the output of three or more power channels in the power transfer device connected to a three-phase power system.

21. The method of claim 1 wherein providing a digital PWM signal having stochastic characteristics and control information is accomplished prior to the moment when it is required.

22. The method of claim 1 wherein providing a digital PWM signal having stochastic characteristics and control information is accomplished outside the PWM control device where it is required.

23. A computational system and circuit comprising:
means for generating a pulse width modulation (PWM) control signal for a power transfer device, comprising:
means for providing a digital PWM signal having stochastic characteristics and control information by combining control pattern information with stochastic information, wherein at least one control pattern embodied in the digital PWM signal can determine an output of the power transfer device; and
means for storing one or more of the digital PWM signals in a digital storage device so as to allow the digital PWM signals to control the output of the power transfer device wherein retrieving one or more digital PWM signals from the stored digital PWM signals is a control step.

24. The computational system and circuit of claim 23 further comprising means for providing a digital PWM signal having stochastic characteristics and control information wherein the digital PWM signal embodies one or more characteristics in regard to the power transfer device output.

25. The computational system and circuit of claim 24 wherein one or more provided digital PWM signals are configured to minimize at least one parameter from among harmonic parameters, is configured to minimize audible noise from the power transfer device, is configured to minimize component vibration in the power transfer device, is configured to reduce unnecessary switching events, is configured to reduce audible noise in power utilization equipment connected to the power transfer device, is configured to minimize component vibration in power utilization equipment connected to the power transfer device, or is configured to reduce frequency-domain energy peaks from current components in the power transfer device.

26. The computational system and circuit of claim 24 wherein one or more provided digital PWM signals embody at least one from among: (a) a distribution of one or more discrete frequency component energies among two or more discrete frequency components, (b) a distribution of energy from at least one discrete frequency component across portions of the continuous spectrum, (c) a distribution of one or more peak densities of frequency energy from narrow segments of the continuous spectrum to wider segments of the continuous spectrum, (d) a distribution of deterministic frequency signatures and stochastic frequency signatures exhibited in the frequency domain, (e) a redistribution of frequency energy to segments of the frequency spectrum that avoid those portions of the spectrum that are unsuitable for the power transfer device, and (f) a redistribution of frequency energy and a reshaping of an output waveform to compensate for harmonic components in the output waveform.

27. The computational system and circuit of claim 24 wherein one or more provided digital PWM signals are created, at least in part, by hand coding a digital PWM signal representation.

28. The computational system and circuit of claim 24 wherein one or more provided digital PWM signals are created, at least in part, by calculating an incremental change based on a similar digital PWM signal representation.

29. The computational system and circuit of claim 24 wherein one or more provided digital PWM signals are created, at least in part, by defining two or more digital PWM signal representations and selecting among the representations by measuring the best representation in regard to the power transfer device output.

30. The computational system and circuit of claim 24 wherein one or more provided digital PWM signals are created, at least in part, by deriving through calculation an ideal digital PWM signal representation.

31. The computational system and circuit of claim 23 wherein selecting from among two or more stored digital signals is a control step.

32. The computational system and circuit of claim 31 wherein selecting from among two or more stored digital PWM signals further comprises means for sensing one or more feedback signals associated with the power transfer device and utilizing an algorithm to select from among stored digital PWM signals.

33. The computational system and circuit of claim 31 wherein selecting from among two or more stored digital signals further comprises means for sensing one or more feedback signals associated with the power transfer device and assigning a bin value wherein the bin value causes selection and utilization of one or more of the stored digital PWM signals.

34. The computational system and circuit of claim 31 wherein selecting from among two or more stored digital signals further comprises means for sensing one or more feedback signals associated with the power transfer device and assigning values in a matrix wherein a range of matrix values relate to selection and utilization of one or more of the stored digital PWM signals.

35. The computational system and circuit of claim 23 wherein the stored digital PWM signals are encoded, packed, or organized in regard to storage capacity and retrieval speed.

36. The computational system and circuit of claim 35 wherein the stored digital PWM signals are encoded or packed as a series of increasing integer values so that one list or array encodes the values for multiple levels of output of the power transfer device.

37. The computational system and circuit of claim 35 wherein the stored digital PWM signals are stored as a series of “1” and “0” values relating to PWM control values in specific time slots.

38. The computational system and circuit of claim 35 wherein the stored digital PWM signals are stored as a series of multi-dimensional arrays or matrices where selecting from among two or more stored digital PWM signals is equivalent to pointing to a specific dimension in an array or matrix.

39. The computational system and circuit of claim 23, further comprising the means for at least one modification of the stored digital PWM signal performed at the power transfer device to allow the stretching of time slots across different time bases, that is, to allow a single stored PWM signal to serve a range of output frequencies of the power transfer device.

40. The computational system and circuit of claim 23 wherein one or more retrieved digital PWM signals are converted to one or more analog PWM signals in the power transfer device.

41. The computational system and circuit of claim 23 wherein one or more retrieved digital PWM signals are used to determine the output of two or more power channels in the power transfer device.

42. The computational system and circuit of claim 23 wherein one or more retrieved digital PWM signals are used to determine the output of three or more power channels in the power transfer device connected to a three-phase power system.

43. The computational system and circuit of claim 23 wherein providing a digital PWM signal having stochastic characteristics and control information is accomplished prior to the moment when it is required.

44. The computational system and circuit of claim 23 wherein providing a digital PWM signal having stochastic characteristics and control information is accomplished outside the PWM control device where it is required.

45. The computational system and circuit of claim 44 further comprising separate computational components, one embodied in the power transfer device and another separate from the power transfer device.

46. The computational system of claim 23, further comprised of a circuit serving to connect with a power transfer circuit of a related-art power transfer device that would otherwise be switched with a related-art PWM control signal, whereby the method is applied and tested so as to be substantially backwards compatible with the related-art power transfer circuit.
